(19) United States
(12) Patent Application Publication
(10) Pub. No.: US 2018/0261665 A1
(43) Pub. Date: Sep. 13, 2018

(54) THIN FILM CAPACITOR AND SEMICONDUCTOR DEVICE

(71) Applicant: Noda Screen Co., Ltd., Aichi (JP)

(72) Inventors: Masamitsu YOSHIZAWA, Koto-ku, Tokyo (JP); Atsunori HATTORI, Komaki-shi, Aichi (JP); Hirotaka HATANO, Komaki-shi, Aichi (JP); Kazuki KUSUMOTO, Tajimi-shi, Gifu (JP)

(21) Appl. No.: 15/564,574

(22) PCT Filed: Dec. 28, 2016
(86) PCT No.: PCT/JP2016/089021

§ 371 Date: Oct. 5, 2017

(51) Int. Cl. H01L 49/02; H01L 23/00; H01L 23/522

(52) U.S. Cl. CPC H01L 28/60; H01L 24/32; H01L 2224/02379; H01L 23/5223; H01L 24/09

(57) ABSTRACT

A thin film capacitor in a redistribution layer of a semiconductor device including a semiconductor chip. The thin film capacitor includes a capacitor body including a first electrode, a dielectric on the first electrode, and a second electrode on the dielectric, and an adhesive portion disposed on a lower surface of the first electrode and used for attaching the thin film capacitor to a protective film of the semiconductor chip. A total of a thickness of the capacitor body and a thickness of the adhesive portion is 20 μm or smaller.

### TECHNICAL FIELD

The present invention relates to a thin film capacitor and a semiconductor device including the thin film capacitor, and more particularly, to a thin film capacitor in a redistribution layer of a semiconductor device including a semiconductor chip.

### BACKGROUND ART

The technology disclosed in Patent Document 1 is known as a conventional technology relating to a thin film capacitor of this type, for example. Patent Document 1 discloses a thin film capacitor including a positive electrode formed of an aluminum film (valve metal), a dielectric film formed of an anodic oxide film, and a negative electrode formed of a conductive high-polymer material. The thin film capacitor is attached to the redistribution layer and bonded thereto with a silver paste film (conductive adhesive). This configuration enables a high-capacity capacitor to be disposed very near a semiconductor integrated circuit (semiconductor chip).

### RELATED ART DOCUMENT

### Patent Document

Patent Document 1: Japanese Unexamined Patent Application Publication No. 2008-227266

### DISCLOSURE OF THE PRESENT INVENTION

### Problem to be Solved by the Invention

However, the thin film capacitor disclosed in the above-described document has a thickness of 0.1 mm to 0.15 mm(100 μm to 150 μm). Thus, an insulating film included in the redistribution layer has a thickness larger than the thickness required for the formation of redistribution wiring, and the redistribution layer unfortunately has a thickness larger than necessary. Furthermore, when the insulating film such as a polyimide film is formed by a spin coating method, the insulating film may have unevenness due to the large thickness of the thin film capacitor.

A technology in this specification provides a thin film capacitor in a redistribution layer of a semiconductor device, which is less likely to increase the thickness of an insulating film included in the redistribution layer and is less likely to make the insulating film unevenness, and also provides the semiconductor device.

### DISCLOSURE OF THE PRESENT INVENTION

### Means for Solving the Problem

A thin film capacitor disclosed herein is a thin film capacitor in a redistribution layer of a semiconductor device including a semiconductor chip. The thin film capacitor includes a capacitor body including a first electrode, a dielectric on the first electrode, and a second electrode on the dielectric, and an adhesive portion disposed on a lower surface of the first electrode and used for attaching the thin film capacitor to a protective film of the semiconductor chip. A total of a thickness of the capacitor body and a thickness of the adhesive portion is 20 μm or smaller.

In this configuration, the thickness of the thin film capacitor inclusive of the thickness of the adhesive portion is 20 μm or smaller. Thus, the total thickness of the thin film capacitor is generally smaller than the thickness of the redistribution layer, more specifically, smaller than the thickness of the insulating film required for the formation of wiring by using copper plating on the insulating film constituting the redistribution layer. In addition, the small total thickness of the thin film capacitor reduces the possibility that the insulating film will have unevenness when the insulating film such as a polyimide film is formed by a spin coating method. Thus, the insulating film is flat. In other words, in the thin film capacitor having this configuration, the thin film capacitor disposed in the redistribution layer is less likely to increase the thickness of the insulating film of the redistribution layer and is less likely to make the insulating film unevenness.

In the above-described thin film capacitor, the adhesive portion may have a peripheral wall having a taper shape spreading toward a lower side.

This configuration effectively reduces the possibility that the insulating film will have unevenness when the insulating film such as a polyimide film is formed by a spin coating matehood. The thickness of the adhesive portion is larger than that of the capacitor body in many cases. In such cases, the tapered peripheral wall of the adhesive sheet allows the insulating film to be smoothly formed on the thin film capacitor when the insulating film is formed by a spin coating method.

In the above-described thin film capacitor, the thickness of the adhesive portion may be equal to or larger than the thickness of the capacitor body.

In this configuration, the increased proportion of the thickness of the adhesive portion in the thin film capacitor allows the insulating film to be more smoothly formed on the thin film capacitor.

Furthermore, in the above-described thin film capacitor, the adhesive portion, the first electrode, the dielectric, and the second electrode may have rectangular planar shapes decreasing in size in a stepwise fashion from the adhesive portion at the bottom to the second electrode at the top. The adhesive portion, the first electrode, the dielectric, and the second electrode may form staircase-like steps at edge portions thereof in which the adhesive portion at the bottom forms the lowest step and the second electrode at the top forms the highest step.

In this configuration, the staircase-like steps formed by the edge portions of the thin film capacitor reduce the possibility that the insulating film will have unevenness due to the edge portion of the thin film capacitor when the insulating film such as a polyimide film is formed by a spin coating method on the thin film capacitor.

Furthermore, the above-described thin film capacitor may further include a stress relaxation structure configured to relax stress generated in a portion of the dielectric located at an edge portion of the second electrode when the thin film capacitor is attached to the protective film of the semiconductor chip by using the adhesive portion.

With this configuration, the stress relaxation structure prevents the dielectric from being damaged by the stress generated in the dielectric when the thin film capacitor is attached to the protective film of the semiconductor chip. In other words, if the thin film capacitor and the semiconductor chip are not parallel to each other beyond a predetermined degree when the thin film capacitor is attached to the protective film of the semiconductor chip, i.e., if the thin film capacitor in a tilted state is attached to the protective film, force concentrates on the dielectric through the lower corner of the edge portion of the second electrode, and stress is generated in the dielectric due to the force. If the stress is high enough to damage the dielectric, the dielectric is damaged, allowing the second electrode and the first electrode to be electrically connected to each other. However, since the stress relaxation structure reduces the stress generated in the dielectric, the dielectric is unlikely to be damaged in such a way.

Furthermore, in the above-described thin film capacitor, the stress relaxation structure may include an upper conductor portion surrounding the second electrode with a predetermined distance therebetween in a planar view and electrically connected to the first electrode, and a connection portion surrounding the dielectric in a planar view and electrically connecting the first electrode and the upper conductor portion to each other. A height from a lower surface of the adhesive portion to an upper surface of the second electrode may be equal to a height from the lower surface of the adhesive portion to an upper surface of the upper conductor portion.

With this configuration, the stress relaxation structure prevents the dielectric from being damaged by the stress generated in the dielectric when the thin film capacitor is attached to the protective film of the semiconductor chip. Specifically, since the height from the lower surface of the adhesive portion to the upper surface of the second electrode is equal to the height from the lower surface of the adhesive portion to the upper surface of the upper conductor portion, when the thin film capacitor is attached to the protective film of the semiconductor chip, the thin film capacitor is pressed to the semiconductor chip at the upper surface of the second electrode and the upper surface of the upper conductor portion by a predetermined pressing jig. With this configuration, if the thin film capacitor is tilted, the force is distributed to the connection portion through the upper conductor portion, preventing the force from concentrating on the dielectric through the lower corner of the edge portion of the second electrode. Thus, the dielectric is unlikely to be damaged by the stress generated in the dielectric.

Furthermore, in the above-described thin film capacitor, the dielectric may have a through groove surrounding the second electrode at a position outside a region of the second electrode in a planar view, and the connection portion may consist of a conductor filling the through groove.

In this configuration, the connection portion is formed by simply filling the through groove. The formation of the connection portion is easy.

Furthermore, in the thin film capacitor, the adhesive portion may be an adhesive sheet attached to the lower surface of the first electrode.

In this configuration, since the adhesive portion is an adhesive sheet, the formation of the adhesive portion is easy.

Furthermore, a semiconductor device disclosed herein includes a semiconductor chip having a bonding surface having electrode pads including a power electrode, a protective film on the bonding surface, a redistribution layer on the protective film, a thin film capacitor in the redistribution layer, and an adhesive portion on a surface of the first electrode opposite a surface having the dielectric thereon or on the protective film of the semiconductor chip. The redistribution layer includes external connection portions, a redistribution portion connecting the electrode pads and the external connection portions to each other, and an insulating layer having the redistribution portion therein. The thin film capacitor includes a capacitor body including a first electrode, a dielectric on the first electrode, and a second electrode on the dielectric. The thin film capacitor is attached to the protective film by using the adhesive portion. A total of the thickness of the capacitor body and the thickness of the adhesive portion is smaller than the thickness of the insulating layer. The first electrode and the second electrode of the thin film capacitor are connected to the power electrode pads and the external connection portions through the redistribution portion.

With this configuration, in the semiconductor device including the thin film capacitor in the redistribution layer, the thickness of the insulating film in the redistribution layer is less likely to increase and the insulating film is less likely to have unevenness. Since the thin film capacitor is disposed near the semiconductor chip, inductance due to wiring is reduced, achieving excellent high frequency characteristics as a decoupling capacitor.

In the above-described semiconductor device, the total of the thickness of the capacitor body and the thickness of the adhesive portion may be 20 μm or smaller.

Furthermore, in the above-described semiconductor device, the adhesive portion may have a peripheral wall having a taper shape spreading toward a lower side.

Furthermore, in the above-described semiconductor device, the thickness of the adhesive portion may be equal to or larger than the thickness of the capacitor body.

Furthermore, in the above-described semiconductor device, the adhesive portion, the first electrode, the dielectric, and the second electrode may have rectangular planar shapes decreasing in size in a stepwise fashion from the adhesive portion at the bottom to the second electrode at the top. The adhesive portion, the first electrode, the dielectric, and the second electrode may form staircase-like steps at edge portions thereof in which the adhesive portion at the bottom forms the lowest step and the second electrode at the top forms the highest step.

Furthermore, in the above-described semiconductor device, the thin film capacitor may have a stress relaxation structure configured to relax stress generated in a portion of the dielectric located at an edge portion of the second electrode when the thin film capacitor is attached to the protective film of the semiconductor chip by using the adhesive portion.

Furthermore, in the above-described semiconductor device, the stress relaxation structure may include an upper conductor portion surrounding the second electrode with a predetermined space therebetween in a planar view and a connection portion surrounding the dielectric in a planar view. The upper conductor portion may be electrically connected to the first electrode. The connection portion may electrically connect the first electrode and the upper conductor portion to each other. A height from a lower surface of the adhesive portion to an upper surface of the second electrode may be equal to a height from the lower surface of the adhesive portion to an upper surface of the upper conductor portion.

Furthermore, in the above-described semiconductor device, the dielectric may have a through groove surrounding the second electrode at a position outside a region of the second electrode in a planar view, and the connection portion may consist of a conductor filling the through groove.

Furthermore, in the above-described semiconductor device, the redistribution layer may be a multi-layer redistribution layer including a multi-layer redistribution portion, the multi-layer redistribution portion may include fan-out wiring allowing an arrangement pitch of the electrode pads to be larger. The first electrode and the second electrode may be connected to the external connection portions through the fan-out wiring.

With this configuration, as a semiconductor device including a thin film capacitor in the redistribution layer, a fan-out wafer level packaging (FOWLP) semiconductor device is formed.

Furthermore, the above-described semiconductor device may further include the thin film capacitor in a portion of the redistribution layer outside a region corresponding to the semiconductor chip in a planar view.

With this configuration, in a FOWLP semiconductor device, the total capacity of a decoupling capacitor is made larger.

Furthermore, the above-described semiconductor device may further include a laminated ceramic capacitor on a surface of the redistribution layer. The laminated ceramic capacitor may be connected to the thin film capacitor in the portion of the redistribution layer.

With this configuration, in a FOWLP semiconductor device, the total capacity of a decoupling capacitor is made further larger as necessary.

Furthermore, in the above-described semiconductor device, the adhesive portion may be an adhesive sheet attached to the lower surface of the first electrode.

Furthermore, the above-described semiconductor device may further include an adhesive layer on the protective film as the adhesive portion.

### Advantageous Effect of the Invention

According to the invention, a thin film capacitor in the redistribution layer is less likely to increase the thickness of the insulating film included in the redistribution layer and is less likely to make the insulating film unevenness.

### BRIEF DESCRIPTION OF THE DRAWINGS

FIG. 1 is a schematic cross-sectional view of a semiconductor device according to a first embodiment.

FIG. 2 is a schematic cross-sectional view illustrating steps of producing a thin film capacitor according to the first embodiment.

FIG. 3 is a schematic cross-sectional view illustrating steps of producing the thin film capacitor, which follow the steps in FIG. 2.

FIG. 4 is a schematic explanatory view illustrating some steps in a method of producing a semiconductor device.

FIG. 5 is a schematic cross-sectional view illustrating another example of a thin film capacitor according to the first embodiment.

FIG. 6 is a schematic cross-sectional view illustrating a thin film capacitor according to a second embodiment.

FIG. 7 is a schematic plan view of the thin film capacitor.

FIG. 8 is a schematic cross-sectional view illustrating steps of producing the thin film capacitor according to the second embodiment.

FIG. 9 is a schematic cross-sectional view illustrating steps of producing the thin film capacitor, which follow the steps in FIG. 8.

FIG. 10 is a schematic cross-sectional view illustrating another method of producing the thin film capacitor according to the second embodiment.

FIG. 11 is a schematic cross-sectional view illustrating another example of the thin film capacitor according to the second embodiment.

FIG. 12 is a schematic cross-sectional view illustrating a semiconductor device of another example.

FIG. 13 is a schematic cross-sectional view illustrating a semiconductor device of another example.

### MODE FOR CARRYING OUT THE INVENTION

### First Embodiment

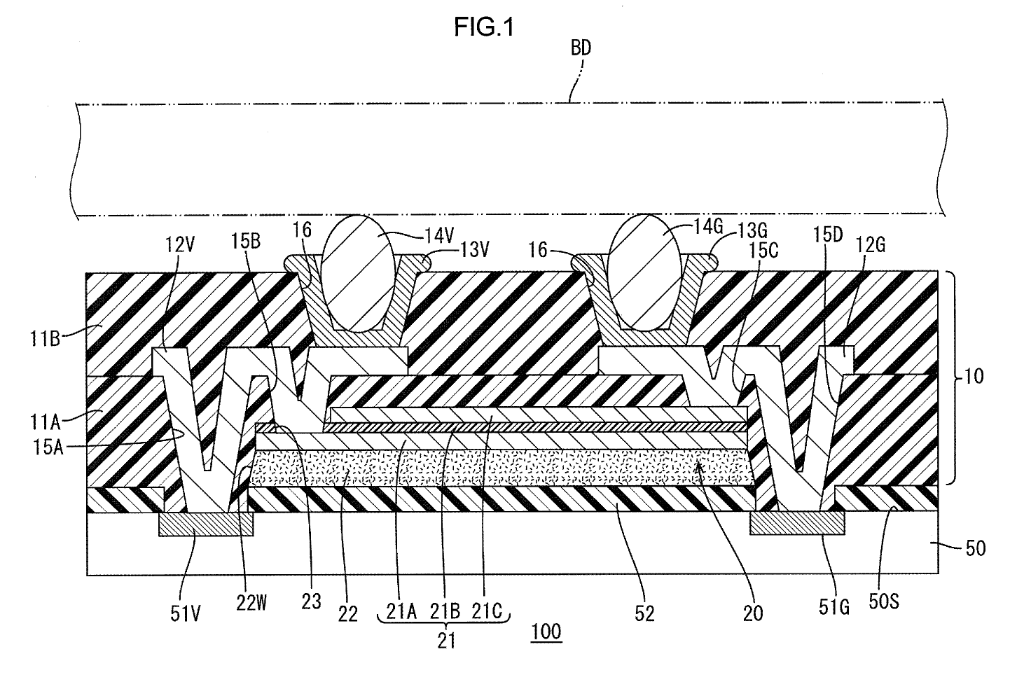

A first embodiment is described with reference to FIG. 1 to FIG. 5. The same reference numerals in the drawings refer to the same or similar components.

### 1. Configuration of Semiconductor Device

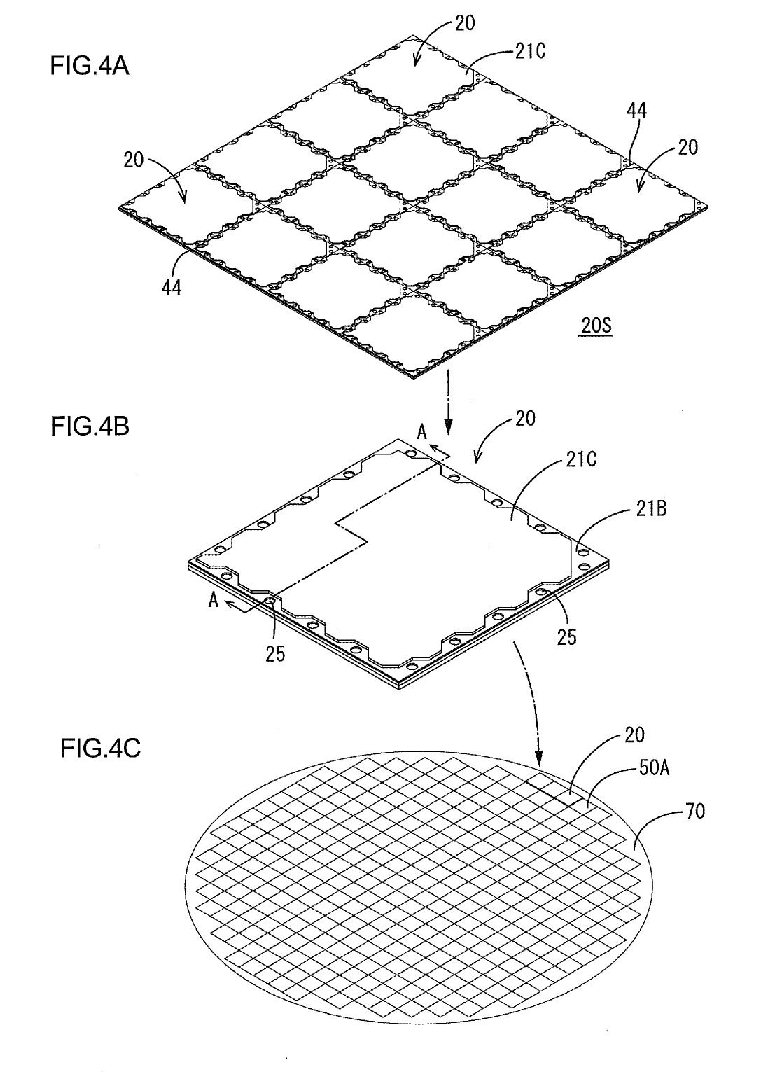

As illustrated in FIG. 1, a semiconductor device 100 is a wafer-level package (WLP) semiconductor device and includes a redistribution layer 10 and an LSI chip (one example of a semiconductor chip) 50 as major components. FIG. 1 is a cross-sectional view of the semiconductor device 100 taken along a dot-and-dash line A-A in FIG. 4B.

A plurality of electrode pads 51 are disposed on a bonding surface 50S of the LSI chip 50, which is a surface to be bonded. As illustrated in FIG. 1, the electrode pads 51 include power electrode pads 51G and 51V for supplying power to the LSI chip 50. In this embodiment, through the redistribution layer 10, a power voltage Vdd is applied to the power electrode pad 51V and a ground voltage Vg is applied to the power electrode pad 51G, for example. Hereinafter, symbols suffixed with the letter “V” indicate components to which the power voltage Vdd is applied and symbols suffixed with the letter “G” indicate components to which the ground voltage Vg is applied.

Furthermore, a protective film 52 is disposed on the bonding surface 50S, more specifically, on the bonding surface 50S except for the electrode pads 51. The redistribution layer 10 is disposed on the protective film 52. The protective film 52 is a nitride film such as a SiN film, for example.

As illustrated in FIG. 1, the redistribution layer 10 includes laminated two-layered insulating layers (11A and 11B). The two-layered insulating layers (11A and 11B) are formed of polyimide resin cured after being applied by a spin coating method, for example.

As illustrated in FIG. 1, the thin film capacitor 20 is in the first insulating layer (a stress-relaxation coating layer) 11A, which is the first layer closest to the bonding surface 50S. The first insulating layer 11A is one example of an “insulating layer”.

Furthermore, external connection pads 13 and soldering balls 14 connected to the external connection pads 13 are in the second insulating layer (a redistribution cover coating layer) 11B, which is the second layer. The soldering balls 14 allow the semiconductor device 100 to be connected to a board BD such a mother board. The external connection pads 13 and the soldering balls 14 are examples of an external connection portion.

Furthermore, the redistribution layer 10 includes redistribution portions 12 connecting the electrode pads 51 and the external connection pads 13 to each other. The redistribution portions 12 are formed of copper plating, for example. Furthermore, as illustrated in FIG. 1, a first electrode 21A and a second electrode 21C of the thin film capacitor 20, which is described later, are connected to the electrode pads 51 and the external connection pads 13 through the redistribution portions 12. More specifically, the first electrode 21A is connected to the power electrode pad 51V and the external connection pad 13V through the redistribution portion 12V. The second electrode 21C is connected to the power electrode pad 51G and the external connection pad 13G through the redistribution portion 12G. In other words, the polarity of the first electrode 21A is positive and that of the second electrode 21c is negative. The polarity of the first electrode 21A and that of the second electrode 21C are not limited to this and may be reversed.

### 1-1. Configuration of Thin Film Capacitor

As illustrated in FIG. 1, the thin film capacitor 20 is a capacitor in the redistribution layer 10 of the semiconductor device 100 including the LSI chip 50. The thin film capacitor 20 includes a capacitor body 21 and an adhesive sheet 22. The adhesive sheet 22 is a die attach film (DAF), for example. The adhesive sheet 22 is one example of an adhesive portion.

As illustrated in FIG. 1, the capacitor body 21 includes the first electrode 21A, a dielectric 21B on the first electrode 21A, and the second electrode 21C on the dielectric 21B. As illustrated in FIG. 1, the adhesive sheet 22 is attached to a lower surface of the first electrode 21A and is used to attach the thin film capacitor 20 to the protective film 52 of the LSI chip 50. The adhesive portion is not limited to the adhesive sheet 22 attached to the lower surface of the first electrode 21A and may be an adhesive agent applied to the lower surface of the first electrode 21A, for example.

The total of the thickness of the capacitor body 21 and that of the adhesive sheet 22, i.e., the thickness of the thin film capacitor 20, is smaller than the thickness of the first insulating layer 11A, and preferably is 20 μm or smaller. In this embodiment, the thickness of the thin film capacitor 20 is 20 μm or smaller. More specifically, the thickness of the first electrode 21A is 2 μm or smaller, the thickness of the dielectric 21B is 1 μm or smaller, and the thickness of the second electrode 21C is 2 μm or smaller. Furthermore, the thickness of the adhesive sheet 22 is 5 μm or larger and 10 μm or smaller.

Furthermore, as illustrated in FIG. 1, for example, the adhesive sheet has a peripheral wall 22W having a taper shape spreading toward the lower side.

### 2. Method of Producing Semiconductor Device

2-1. Method of Producing Thin Film Capacitor

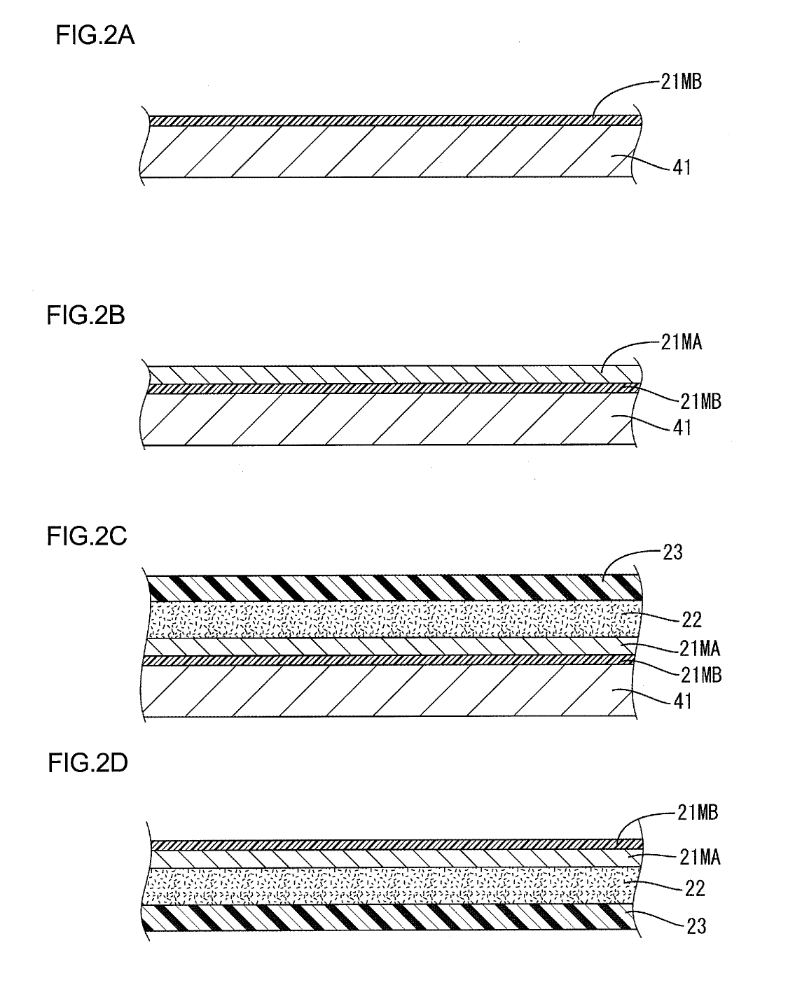

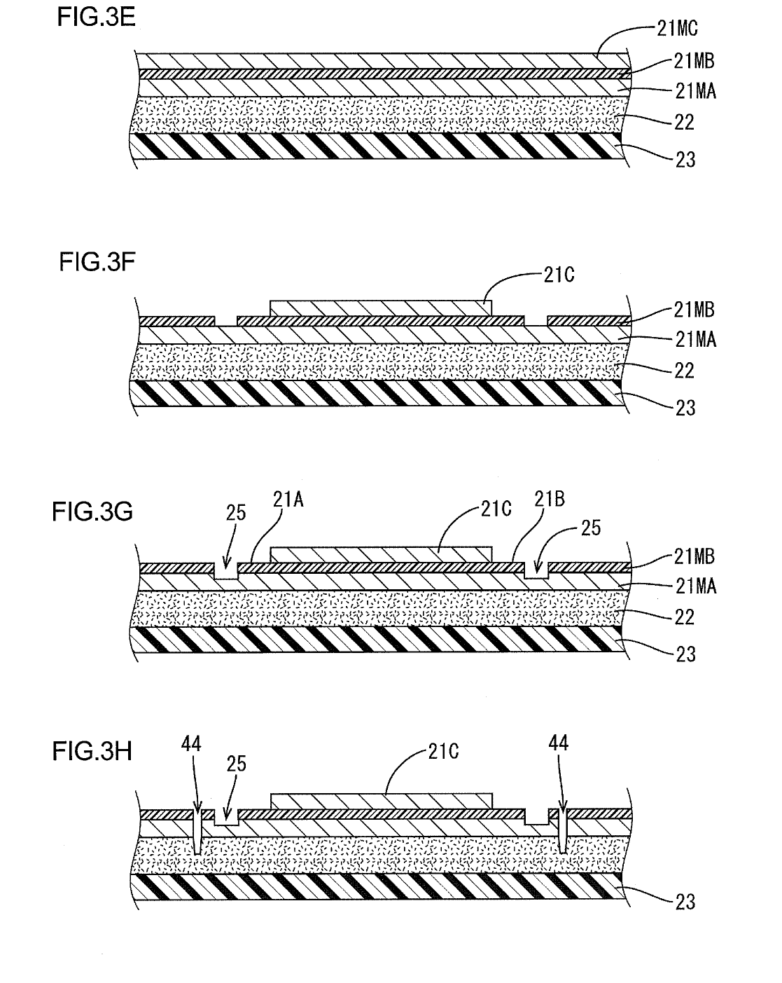

First, with reference to FIG. 2 and FIG. 3, one example of the method of producing the thin film capacitor 20 is described. The thin film capacitors 20 in a thin film capacitor sheet 20S illustrated in FIG. 4A are separated to be individual thin film capacitors 20. In the following explanation, one of the separated thin film capacitors 20 is described. Furthermore, the steps of producing the thin film capacitor 20 illustrated in FIG. 2 and FIG. 3 are merely examples and are not limited to these examples.

In the method, first, as illustrated in FIG. 2A, an STO (strontium titanate) film 21MB is formed by an AS (aerosol) CVD method, for example, on a dry-cleaned base 41. The thickness of the STO film 21MB is in a range of 0.1 μm to 0.4 μm, for example. The STO film 21MB turns into the dielectric 21B of the thin film capacitor 20. In this embodiment, the base 41 is formed of aluminum foil. The metal foil used as the base is not limited to the aluminum foil and may be copper or nickel foil, for example. Furthermore, the dielectric is not limited to the STO film 21MB.

Next, as illustrated in FIG. 2B, a metal thin film 21MA, which turns into the first electrode 21A of the thin film capacitor 20, is formed on the STO film 21MB. The metal thin film 21MA is a Cu (copper) thin film, for example. The Cu thin film is formed by a vapor deposition method, for example. The thickness of the metal thin film 21MA is 2 μm or smaller, for example.

Next, as illustrated in FIG. 2C, an adhesive sheet 22 with a protective film 23 is attached to the metal thin film 21MA. Then, as illustrated in FIG. 2D, the aluminum base 41 is removed by etching, for example, such that the surface of the STO film 21MB opposite the surface having the metal thin film 21MA thereon is exposed. In FIG. 2D and the following figures, the state in FIG. 2C is illustrated upside down.

Next, as illustrated in FIG. 3E, a metal thin film 21MC, which turns into the second electrode 21C of the thin film capacitor 20, is formed on the exposed STO film 21MB. The metal thin film 21MC is a Cu (copper) thin film, for example, as the first electrode 21A. The Cu thin film is formed by a vapor deposition method, for example. The thickness of the metal thin film 21MC is 2 μm or smaller, for example.

Next, as illustrated in FIG. 3F, the metal thin film 21MC is patterned to form the second electrode 21C. The planar shape of the second electrode 21C is rectangular and is almost square (see FIG. 4A). Then, as illustrated in FIG. 3G, through holes 25 extending to the metal thin film 21MA are formed in the STO film 21MB with a laser, for example. Then, as illustrated in FIG. 3H, grooves 44 for separating the thin film capacitors 20 are formed near the through holes 25 with a laser, for example. The grooves 44 surround the second electrodes 21C (see FIG. 4A). As illustrated in FIG. 3H, the grooves 44 extend to the inside of the protective film 23 in depth. The formation of the grooves 44 results in patterning of the metal thin film 21MA and the STO film 21MB, and the first electrode 21A and the dielectric 21B are formed. Thus, the thin film capacitor 20 is formed. Specifically, the thin film capacitor sheet 20S illustrated in FIG. 4A is formed.

2-2. Method of Producing Semiconductor Device

Next, with reference to FIG. 1 and FIG. 4, a method of producing the semiconductor device 100 is briefly described.

The thin film capacitor 20 with the protective film 23 is individually separated from the thin film capacitor sheet 20S illustrated in FIG. 4A (see FIG. 4B). The protective film 23 is removed from the separated thin film capacitor 20, and the thin film capacitor 20 is attached to the protective film 52 of the LSI chip 50A after a front-end process of producing a semiconductor chip and before dicing (see FIG. 4C).

Next, in a back-end process of producing a semiconductor chip, the redistribution layer 10 is formed by a well-known method on the protective film 52 to which the thin film capacitor 20 has attached. First, the first insulating layer 11A is formed by a spin coating method, for example. Then, via holes (15A to 15D) for connecting the first electrode 21A and the second electrode 21C of the thin film capacitor 20 to the power electrode pads 51 through the redistribution portions 12 are formed. Subsequently, the redistribution portions 12 are formed on the inner walls of the via holes (15A to 15D) and on the first insulating layer 11A by using copper plating, for example.

Next, the second insulating layer 11B is formed by a spin coating method, for example, on the first insulating layer 11A having the redistribution portions 12 and inside the via holes (15A to 15D). Then, via holes (16A and 16B) for connecting the first electrode 21A and the second electrode 21C of the thin film capacitor 20 to the external connecting pads 13 through the redistribution portions 12 are formed. Subsequently, the external connection pads 13 are formed on the inner wall of the via holes (16A and 16B) by using a metal having high solder wettability, and the soldering balls 14 are formed on the external connection pads 13. Then, a semiconductor wafer 70 is diced to form the separated semiconductor devices 100. Here, the external connection pad 13 is preferably an under bump metal (UBM).

### 3. Effects of First Embodiment

The thickness of the thin film capacitor 20 inclusive of the thickness of the adhesive sheet 22 is 20 μm or smaller. Thus, the total thickness of the thin film capacitor 20 is generally smaller than the thickness of the redistribution layer 10, more specifically, smaller than the thickness of the first insulating layer 11A required for the formation of the redistribution portion 12 by using copper plating on the first insulating layer 11A constituting the redistribution layer 10. In addition, the small total thickness of the thin film capacitor 20 reduces the possibility that the first insulating layer 11A will have unevenness when the first insulating layer 11A such as a polyimide film is formed by a spin coating method. Thus, the first insulating layer 11A is flat. In other words, the thin film capacitor 20 according to the first embodiment, which is disposed in the redistribution layer 10, is less likely to increase the thickness of the first insulating layer 11A of the redistribution layer 10 and is less likely to make the first insulating layer 11A unevenness.

Furthermore, the peripheral wall 22W of the adhesive sheet 22 has a taper shape spreading toward a lower side. This effectively reduces the possibility that the first insulating layer 11A will have unevenness when the first insulating layer 11A such as a polyimide film is formed by a spin coating matehood. The thickness of the adhesive sheet 22 is larger than that of the capacitor body 21 in many cases. In such cases, the tapered peripheral wall 22W of the adhesive sheet allows the first insulating layer 11A to be smoothly formed on the thin film capacitor 20 when the first insulating layer 11A is formed by a spin coating method.

Furthermore, in the configuration of the semiconductor device 100 according to the first embodiment, the thin film capacitor 20 is disposed near the LSI chip 50. This reduces inductance due to wiring between the LSI chip 50 and the thin film capacitor 20, achieving excellent high frequency characteristics as a decoupling capacitor.

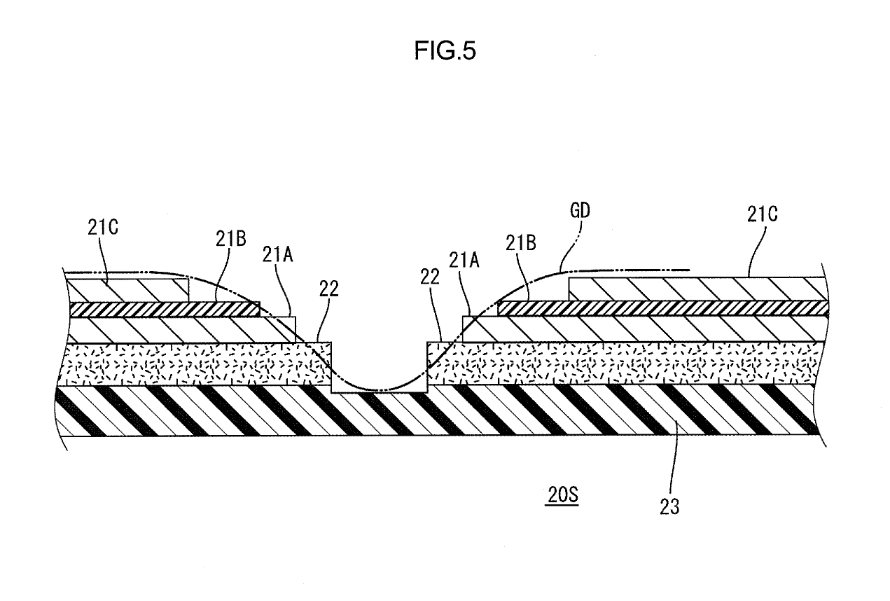

The configuration of the thin film capacitor 20 is not limited to that illustrated in FIG. 1. For example, the adhesive sheet 22, the first electrode 21A, the dielectric 21B, and the second electrode 21C may have rectangular planar shapes decreasing in size in a stepwise fashion from the adhesive sheet 22 on the bottom toward the second electrode 21C on the top. As illustrated in FIG. 5, the adhesive sheet 22, the first electrode 21A, the dielectric 21B, and the second electrode 21C may form staircase-like steps at the edge portions thereof in which the adhesive sheet 22 at the bottom forms the lowest step and the second electrode 21C at the top forms the highest step. In this configuration, since the edge portions in the thin film capacitor 20 form the staircase-like steps, when the first insulating layer 11A such as a polyimide film is formed by a spin coating method on the thin film capacitor 20 attached to the protective film 52 of the LSI chip 50, the first insulating layer 11A is further less likely to have unevenness possibly generated by the edge portions of the thin film capacitor 20. In this case, the peripheral wall 22W of the adhesive sheet does not need to have a taper shape.

As illustrated in FIG. 5, when the thin film capacitor 20 is separated from the thin film capacitor sheet 20S, the steps may be smoothed by a laser beam having an intensity distribution of Gaussian beam shape GD.

### Second Embodiment

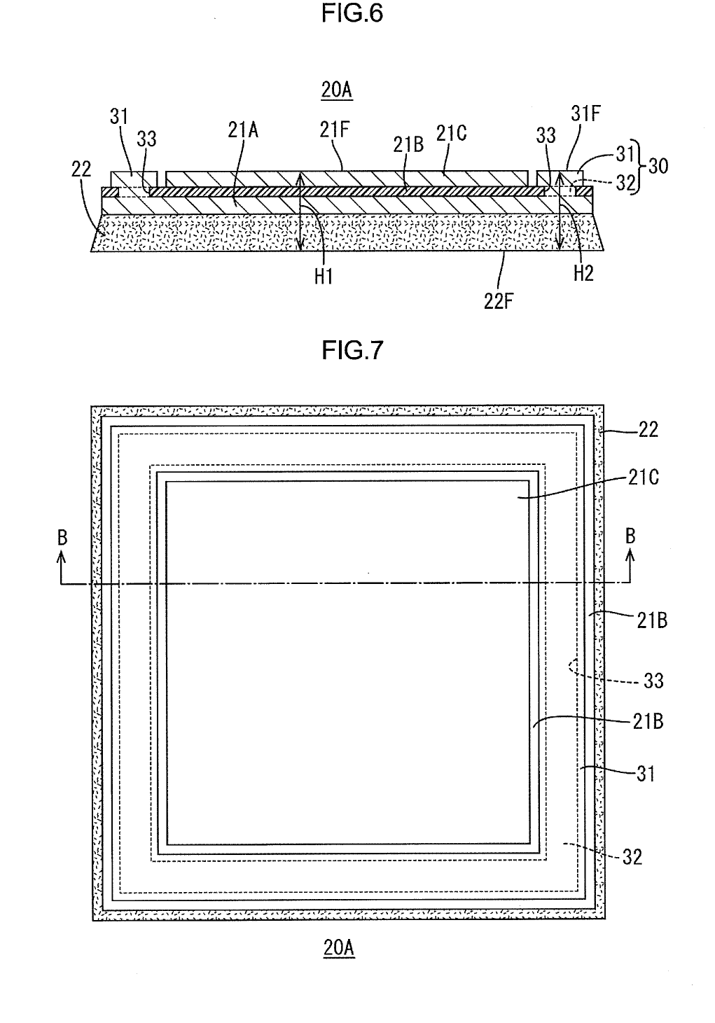

Next, with reference to FIG. 6 to FIG. 11, a second embodiment is described. The second embodiment differs from the first embodiment only in the configuration of a thin film capacitor 20A. Thus, only the thin film capacitor 20A is described. Components identical to those in the first embodiment are assigned the same reference numerals as those in the first embodiment and are not described in detail.

As illustrated in FIG. 6, the thin film capacitor 20A according to the second embodiment includes a stress relaxation structure 30. The stress relaxation structure 30 is configured to relax stress generated in a portion of the dielectric 21B located at the edge portion of the second electrode 21C when the thin film capacitor 20A is attached to the protective film 52 of the LSI chip 50 by using the adhesive sheet 22.

The stress relaxation structure 30 includes an upper conductor portion 31 and a connection portion 32. The upper conductor portion 31 surrounds the second electrode 21C with a predetermined space therebetween in a planar view (see FIG. 7) and is electrically connected to the first electrode 21A through the connection portion 32. The connection portion 32 surrounds the dielectric 21B in a planar view and electrically connects the first electrode 21A and the upper conductor portion 31 to each other. The upper conductor portion 31 is a connection electrode for connecting the first electrode 21A to the power electrode pad 51V and to the external connection pad 13V. Here, a height H1 from a lower surface 22F of the adhesive sheet to an upper surface 21F of the second electrode 21C is equal to a height H2 from the lower surface 22F of the adhesive sheet to an upper surface 31F of the upper conductor portion 31 (see FIG. 6).

Furthermore, the dielectric 21B has a through groove 33 surrounding the second electrode at a position outside a region of the second electrode 21C in a planar view, and the connection portion 32 consists of a conductor filling the through groove 33. Thus, the connection portion 32 is formed by simply filling the through groove 33. The formation of the connection portion 32 is easy.

### 4. Method of Producing Thin Film Capacitor of Second Embodiment

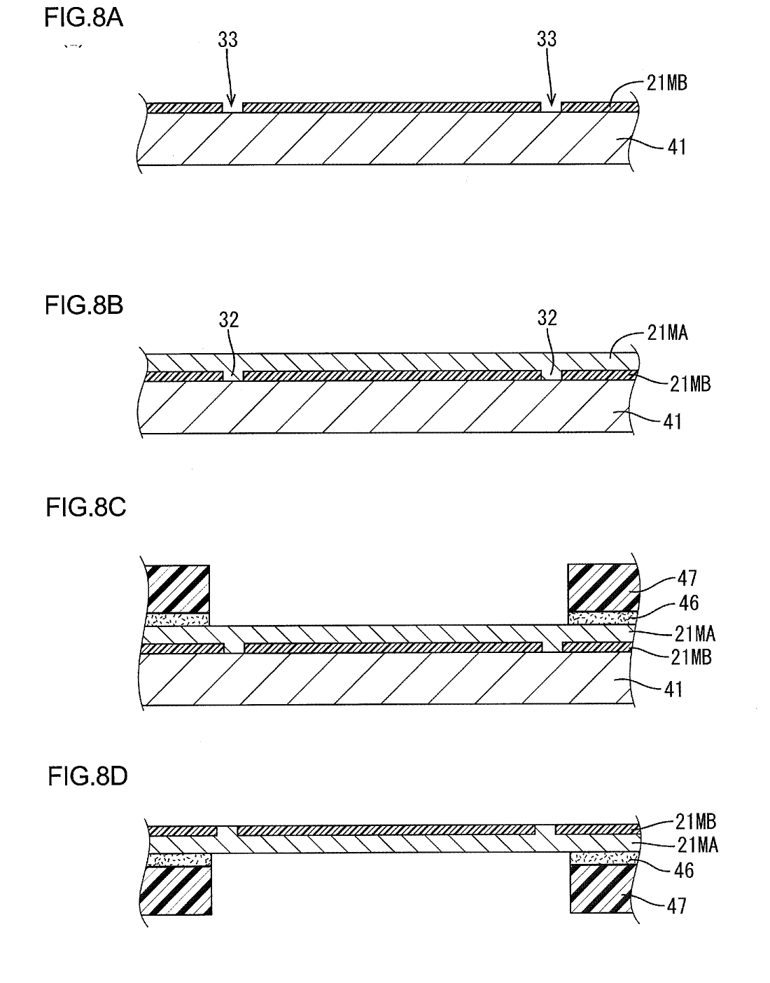

Next, with reference to FIG. 8 to FIG. 10, a method of producing the thin film capacitor 20A according to the second embodiment is described.

First, as illustrated in FIG. 8A, the STO film 21MB on the base 41 is patterned to form the through groove 33. Then, as illustrated in FIG. 8B, the metal thin film 21MA, which turns into the first electrode 21A of the thin film capacitor 20, is formed on the STO film 21MB. The metal thin film 21MA is formed of a Cu (copper) thin film, for example. In this step, the Cu thin film fills the through groove 33 to form the connection portion 32.

Next, as illustrated in FIG. 8C, a supporting member 47 with an adhesive layer 46 is attached to the metal thin film 21MA. The supporting member 47 has a frame-like shape. Then, as illustrated in FIG. 8D, the aluminum base 41 is removed by etching, for example, such that the surface of the STO film 21MB opposite the surface having the metal thin film 21MA thereon is exposed. In FIG. 8D and the following figures, the state in FIG. 8C is illustrated upside down.

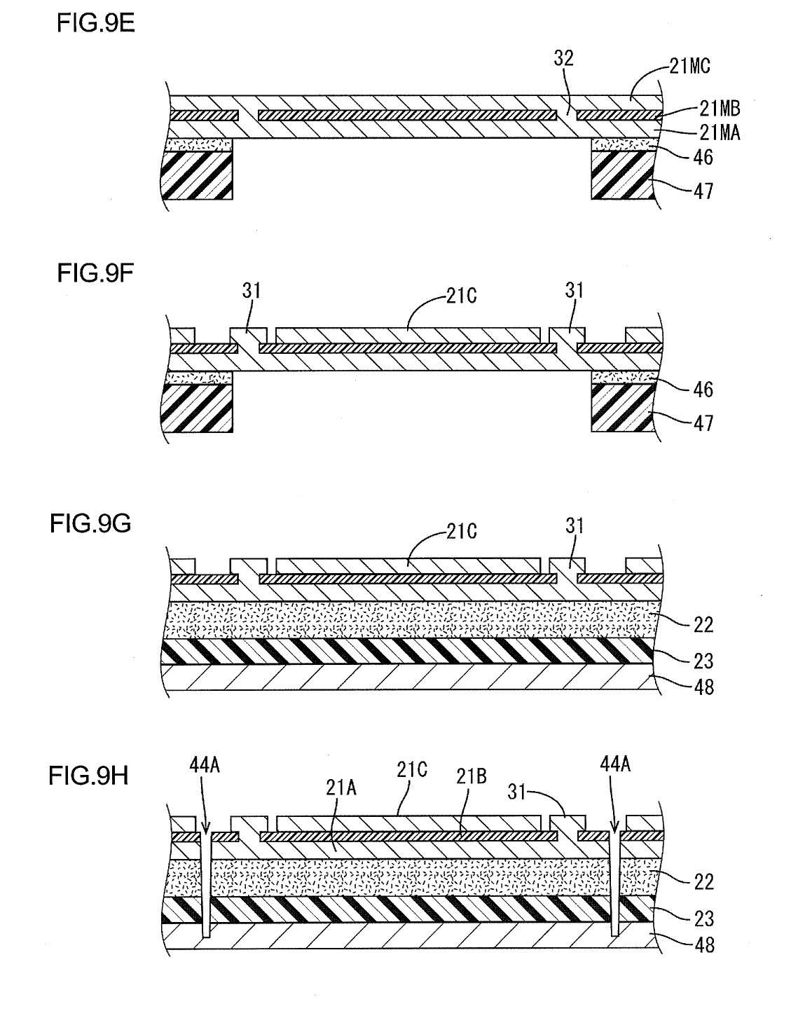

Next, as illustrated in FIG. 9E, the metal thin film 21MC, which turns into the second electrode 21C of the thin film capacitor 20, is formed on the exposed STO film 21MB and the connection portion 32. The metal thin film 21MC is formed of a Cu (copper) thin film, for example, as the first electrode 21A.

Next, as illustrated in FIG. 9F, the metal thin film 21MC is patterned to form the second electrode 21C and the upper conductor portion 31 (see FIG. 7). Then, as illustrated in FIG. 9G, the supporting member 47 is removed, and the adhesive sheet 22 with the protective film 23 supported by a different supporting member 48 is attached to the metal thin film 21MA.

Next, as illustrated in FIG. 9H, grooves 44A for separating the thin film capacitors 20 are formed with a laser, for example. The groove 44A surrounds the upper conductor portion 31 and extends to the inside of the supporting member 48 in depth as illustrated in FIG. 9H. The formation of the grooves 44A results in patterning of the metal thin film 21MA and the STO film 21MB, and thus the first electrode 21A, the dielectric 21B, and the upper conductor portion 31 (the stress relaxation structure 30) are formed. Thus, the thin film capacitor 20A is formed.

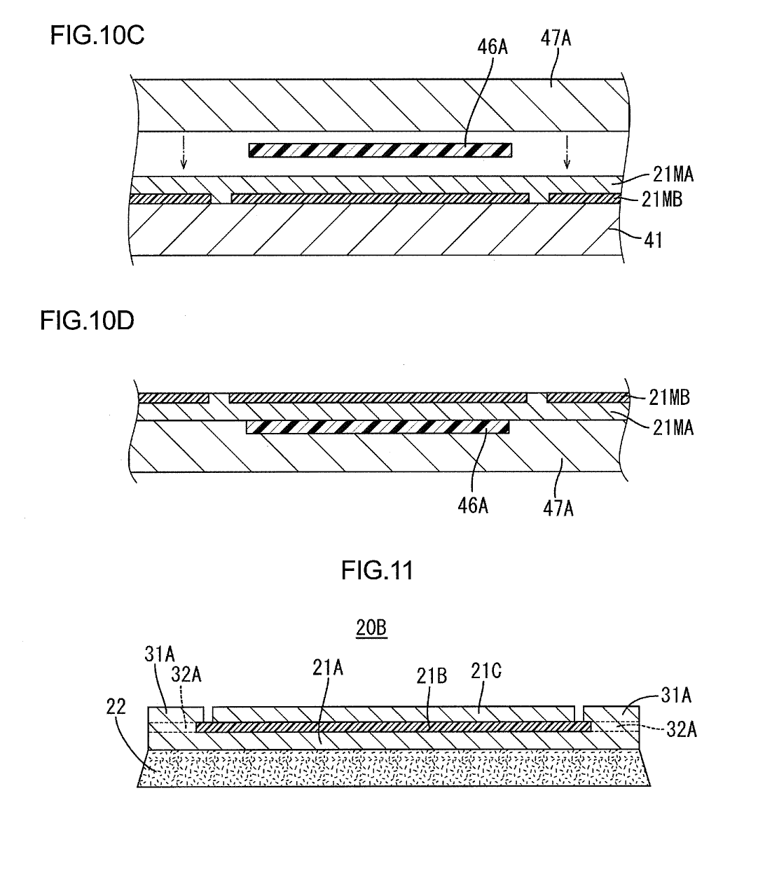

Instead of the frame-shaped supporting member 47 with the adhesive layer 46 illustrated in FIG. 8C and FIG. 8D, a planar adhesive-resistant cover 46A covering the entire planar surface of the thin film capacitor 20 and a supporting member 47A disposed over the cover 46A illustrated in FIG. 10C and FIG. 10D may be employed.

Furthermore, the configuration of the stress relaxation structure 30 is not limited to that illustrated in FIG. 6. For example, a stress relaxation structure 30A of a thin film capacitor 20B illustrated in FIG. 11 may be employed. The stress relaxation structure 30A includes an upper conductor portion 31A and a connection portion 32A as the stress relaxation structure 30. However, as illustrated in FIG. 11, the stress relaxation structure 30A differs from the stress relaxation structure 30 in that the stress relaxation structure 30A does not include the through groove 33 surrounding the second electrode. In other words, in the stress relaxation structure 30A, the connection portion 32A extends to the outer periphery of the capacitor body 21, eliminating the need for the through groove 33 for forming the connection portion 32A.

### 5. Effects of Second Embodiment

With this configuration, the stress relaxation structure 30 prevents the dielectric 21B from being damaged by the stress generated in the dielectric 21B when the thin film capacitor 20A is attached to the protective film 52 of the semiconductor chip. In other words, if the thin film capacitor 20A and the LSI chip 50 are not parallel to each other beyond a predetermined degree during attachment of the thin film capacitor 20A to the protective film 52 of the semiconductor chip, i.e., if the thin film capacitor 20A in a tilted state is attached to the protective film 52, force concentrates on the dielectric 21B through the lower corner of the edge portion of the second electrode 21C, and stress is generated in the dielectric 21B due to the force. If the stress is high enough to damage the dielectric 21B, the dielectric 21B is damaged, allowing the second electrode 21C and the first electrode 21A to be electrically connected to each other. However, since the stress relaxation structure 30 reduces the stress generated in the dielectric 21B, the dielectric 21B is unlikely to be damaged in such a way.

Specifically, since the height H1 from the lower surface 22F of the adhesive sheet to the upper surface 21F of the second electrode is equal to the height H2 from the lower surface 22F of the adhesive sheet to the upper surface 31F of the upper conductor portion 31, when the thin film capacitor 20A is attached to the protective film 52 of the semiconductor chip, the thin film capacitor 20A is pressed to the LSI chip 50 at the upper surface of the second electrode and the upper surface of the upper conductor portion by a predetermined pressing jig. Thus, if the thin film capacitor 20A is tilted, the force exerted during attachment is distributed to the connection portion 32, for example, through the upper conductor portion 31, preventing the force from concentrating on the dielectric 21B through the lower corner of the edge portion of the second electrode 21C. Thus, the dielectric is unlikely to be damaged by the stress generated in the dielectric 21B.

### Other Embodiments

The present invention is not limited to the embodiments described above and illustrated by the drawings. For example, the following embodiments will be included in the technical scope of the present invention.

(1) In the above-described embodiments, the thickness of the adhesive sheet 22 having the tapered peripheral wall 22W may be equal to or larger than the thickness of the capacitor body 21.

In such a case, when the first insulating film 11A of the redistribution layer 10 is formed by a spin coating method, the increased proportion of the thickness of the adhesive sheet 22 in the thin film capacitor allows the first insulating layer 11A to be more smoothly formed on the thin film capacitor.

(2) In the examples in the above-described embodiments, the adhesive portion of the semiconductor device 100 for attaching the thin film capacitor 20 to the protective film 52 is the adhesive sheet 22 attached to the lower surface of the first electrode 21A of the thin film capacitor 20. However, the adhesive portion is not limited to this. For example, the adhesive portion may be an adhesive layer on the protective film 52 of the LSI chip 50. Specifically, an adhesive or an adhesive resin, for example, may be applied to the semiconductor chip to form an adhesive layer, and then only the capacitor body 21 may be directly disposed on the LSI chip 50. In short, the adhesive portion may be provided on a surface of the first electrode 21A opposite the surface having the dielectric thereon or on the protective film 52 of the LSI chip 50.

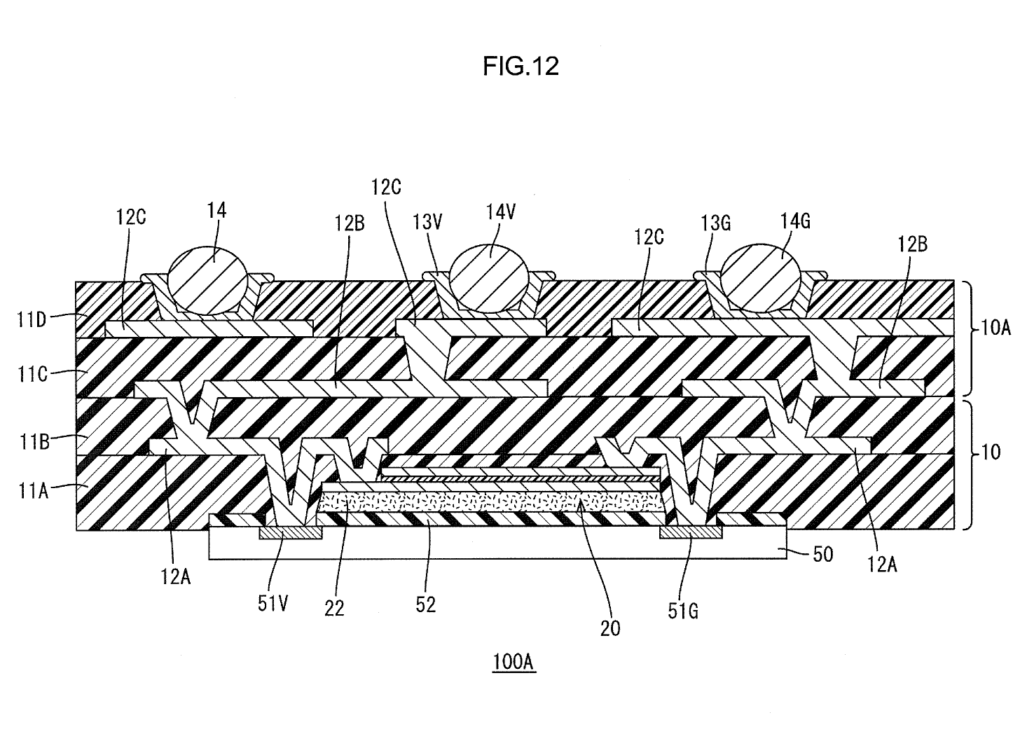

(3) In the above-described embodiments, the configuration of the semiconductor device is not limited to that of the semiconductor device 100 illustrated in FIG. 1. For example, as a semiconductor device 100A illustrated in FIG. 12, the redistribution layer may include a multi-layer redistribution layer (10, 10A) including a multi-layer redistribution portion (12A, 12B, 12C). The multi-layer redistribution portion may include fan-out wiring (12A, 12B, 12C), which makes arrangement pitch of the electrode pads 51 larger. The first electrode 21A and the second electrode 21C may be connected to the external connection portion through the fan-out wiring.

In this case, as a semiconductor device including a thin film capacitor in the redistribution layer, a fan-out wafer level packaging (FOWLP) semiconductor device is formed. In FIG. 12, the multi-layer redistribution layer (10, 10A) including four insulating layers (11A, 11B, 11C, 11D) and three redistribution portions (12A, 12B, 12C) is illustrated as an example. However, the configuration of the multi-layer redistribution layer is not limited to this.

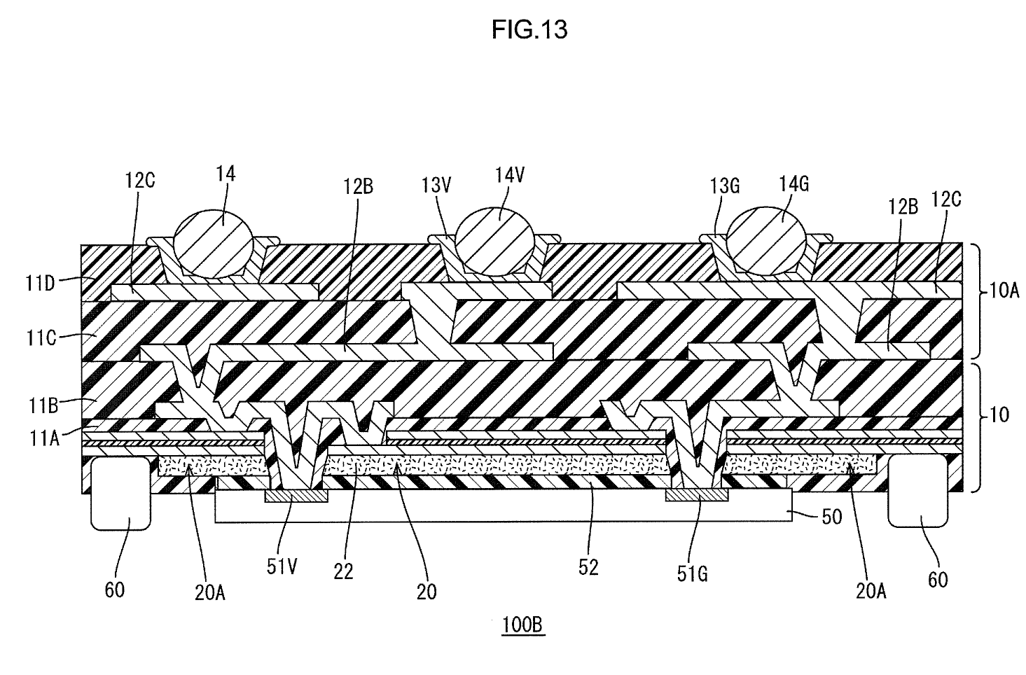

(4) Alternatively, as a semiconductor device 100B illustrated in FIG. 13, a thin film capacitor 20A may be further provided in a portion of a redistribution layer outside a region corresponding to the semiconductor chip in a planar view.

In such a case, in a FOWLP semiconductor device, a total capacity of a decoupling capacitor is made larger.

Furthermore, as the semiconductor device 100B illustrated in FIG. 13, a laminated ceramic capacitor 60 connected to the thin film capacitor 20A in the portion of the redistribution layer may be further provided on a surface 10S of the redistribution layer.

In such a case, in a FOWLP semiconductor device, a total capacity of a decoupling capacitor is further made larger as necessary.

### EXPLANATION OF SYMBOLS

10 redistribution layer
11A first insulating layer
11B second insulating layer
12 redistribution portion
12A, 12B, 12C fan-out wiring (redistribution portion)
13 external connection pad (external connection portion)
14 soldering ball (external connection portion)
20, 20A, 20B thin film capacitor
21 capacitor body
21A first electrode
21B dielectric
21C second electrode
22 adhesive sheet (adhesive portion)
22W peripheral wall of adhesive sheet
30, 30A stress relaxation structure
31, 31A upper conductor portion
32, 32A connection portion
50 LSI chip (semiconductor chip)
50S bonding surface
51G, 51V power supply electrode pad (electrode pad)
52 protective film
60 laminated ceramic capacitor
100, 100A, 100B semiconductor device

1. A thin film capacitor in a redistribution layer of a semiconductor device including a semiconductor chip, the thin film capacitor comprising:
a capacitor body including a first electrode, a dielectric on the first electrode, and a second electrode on the dielectric; and
an adhesive portion disposed on a lower surface of the first electrode and used for attaching the thin film capacitor to a protective film of the semiconductor chip, wherein
a total of a thickness of the capacitor body and a thickness of the adhesive portion is 20 μm or smaller.

2. The thin film capacitor according to claim 1, wherein the adhesive portion has a peripheral wall having a taper shape spreading toward a lower side.

3. The thin film capacitor according to claim 2, wherein the thickness of the adhesive portion is equal to or larger than the thickness of the capacitor body.

4. The thin film capacitor according to claim 1, wherein the adhesive portion, the first electrode, the dielectric, and the second electrode have rectangular planar shapes decreasing in size in a stepwise fashion from the adhesive portion at the bottom to the second electrode at the top, and
the adhesive portion, the first electrode, the dielectric, and the second electrode form staircase-like steps at edge portions thereof in which the adhesive portion at the bottom forms the lowest step and the second electrode at the top forms the highest step.

5. The thin film capacitor according to claim 1, further comprising a stress relaxation structure configured to relax stress generated in a portion of the dielectric located at an edge portion of the second electrode when the thin film capacitor is attached to the protective film of the semiconductor chip by using the adhesive portion.

6. The thin film capacitor according to claim 5, wherein the stress relaxation structure includes:
an upper conductor portion surrounding the second electrode with a predetermined distance therebetween in a planar view and electrically connected to the first electrode; and
a connection portion surrounding the dielectric in a planar view and electrically connecting the first electrode and the upper conductor portion to each other, and
a height from a lower surface of the adhesive portion to an upper surface of the second electrode is equal to a height from the lower surface of the adhesive portion to an upper surface of the upper conductor portion.

7. The thin film capacitor according to claim 6, wherein the dielectric has a through groove surrounding the second electrode at a position outside a region of the second electrode in a planar view, and
the connection portion consists of a conductor filling the through groove.

8. The thin film capacitor according to claim 1, wherein the adhesive portion is an adhesive sheet attached to the lower surface of the first electrode.

9. A semiconductor device comprising:
a semiconductor chip having a bonding surface having electrode pads including a power electrode pad;
a protective film on the bonding surface;
a redistribution layer on the protective film, the redistribution layer including external connection portions, a redistribution portion connecting the electrode pads and the external connection portions to each other, and an insulating layer having the redistribution portion therein;
a thin film capacitor in the redistribution layer, the thin film capacitor including a capacitor body including a first electrode, a dielectric on the first electrode, and a second electrode on the dielectric; and
an adhesive portion on a surface of the first electrode opposite a surface having the dielectric thereon or on the protective film of the semiconductor chip, wherein
the thin film capacitor is attached to the protective film by using the adhesive portion,
a total of a thickness of the capacitor body and a thickness of the adhesive portion is smaller than a thickness of the insulating layer, and
the first electrode and the second electrode of the thin film capacitor are connected to the power electrode pads and the external connection portions through the redistribution portion.

10. The semiconductor device according to claim 9, wherein the total of the thickness of the capacitor body and the thickness of the adhesive portion is 20 μm or smaller.

11. The semiconductor device according to claim 9, wherein the adhesive portion has a peripheral wall having a taper shape spreading toward a lower side.

12. The semiconductor device according to claim 11, wherein the thickness of the adhesive portion is equal to or larger than the thickness of the capacitor body.

13. The semiconductor device according to claim 9, wherein the adhesive portion, the first electrode, the dielectric, and the second electrode have rectangular planar shapes decreasing in size in a stepwise fashion from the adhesive portion at the bottom to the second electrode at the top, and
the adhesive portion, the first electrode, the dielectric, and the second electrode form staircase-like steps at edge portions thereof in which the adhesive portion at the bottom forms the lowest step and the second electrode at the top forms the highest step.

14. The semiconductor device according to claim 9, wherein the thin film capacitor has a stress relaxation structure configured to relax stress generated in a portion of the dielectric located at an edge portion of the second electrode when the thin film capacitor is attached to the protective film of the semiconductor chip by using the adhesive portion.

15. The semiconductor device according to claim 14, wherein the stress relaxation structure includes:
an upper conductor portion surrounding the second electrode with a predetermined space therebetween in a planar view, the upper conductor portion being electrically connected to the first electrode; and
a connection portion surrounding the dielectric in a planar view, the connection portion electrically connecting the first electrode and the upper conductor portion to each other, and
a height from a lower surface of the adhesive portion to an upper surface of the second electrode is equal to a height from the lower surface of the adhesive portion to an upper surface of the upper conductor portion.

16. The semiconductor device according to claim 15, wherein the dielectric has a through groove surrounding the second electrode at a position outside a region of the second electrode in a planar view, and
the connection portion consists of a conductor filling the through groove.

17. The semiconductor device according to claim 9, wherein the redistribution layer is a multi-layer redistribution layer including a multi-layer redistribution portion,
the multi-layer redistribution portion includes fan-out wiring allowing an arrangement pitch of the electrode pads to be larger, and
the first electrode and the second electrode are connected to the external connection portions through the fan-out wiring.

18. The semiconductor device according to claim 17, further comprising the thin film capacitor in a portion of the redistribution layer outside a region corresponding to the semiconductor chip in a planar view.

19. The semiconductor device according to claim 18, further comprising a laminated ceramic capacitor on a surface of the redistribution layer, the laminated ceramic capacitor being connected to the thin film capacitor in the portion of the redistribution layer.

20. The semiconductor device according to claim 9, wherein the adhesive portion is an adhesive sheet attached to the lower surface of the first electrode.

21. The semiconductor device according to claim 9, further comprising an adhesive layer on the protective film as the adhesive portion.
